(19) United States
(12) Patent Application Publication
(10) Pub. No.: US 2007/0126129 A1
(43) Pub. Date: Jun. 7, 2007

(54) Die bonding adhesive tape

(75) Inventors: Yong-Kook Ahn, Yongin-si (KR); Chang-Hoon Sim, Seoul (KR); Kyo-Sung Hwang, Inchon (KR)

Correspondence Address: ROTHWELL, FIGG, ERNST & MANBECK, P.C., 1425 K STREET, N.W., SUITE 800, WASHINGTON, DC, 20005, US

(73) Assignee: Ace Industries Co., Ltd., Gwangju-si (KR)

(21) Appl. No.: 11/633,414

(22) Filed: Dec. 5, 2006

(30) Foreign Application Priority Data
Dec. 6, 2005 (KR) 10-2005-0118238

(51) Int. Cl. H01L 23/48

(52) U.S. Cl. 257/783; 257/E23.018

(57) ABSTRACT

Disclosed is a die bonding adhesive tape, which eliminates the requirement for additional adhesive tape for attaching a ring frame, decreases the curing time period upon die bonding, essentially prevents the transfer and diffusion of low-molecular-weight compounds between an adhesive film and an adhesive layer on a base substrate to thus exhibit excellent pick-up performance when picking up a die, and easily separates an adhesive film having a die from an adhesive layer on a base substrate when picking up slim and large dies. The die bonding adhesive tape of the invention includes a base substrate and an adhesive layer formed on the base substrate, has a structure in which a core film having a die bonding adhesive film attached thereto is bonded onto the adhesive layer, and enables direct die bonding via dicing and then die pick-up in a state of being mounted on a wafer.

### RELATED APPLICATIONS

The present disclosure relates to subject matter contained in priority Korean Application No. 10-2005-0118238 filed on 6 Dec. 2005, which is herein expressly incorporated by reference in its entirety.

### BACKGROUND OF THE INVENTION

1. Field of the Invention

The present invention relates, generally, to a die bonding adhesive tape, and more particularly, to a die bonding adhesive tape, which functions to increase the working efficiency and decrease the working time period in a semiconductor manufacturing process.

2. Description of the Related Art

In a semiconductor manufacturing process, a wafer having a large diameter is divided into small chips through a dicing process, and the divided small chips are subjected to a series of processes including washing, drying, expanding, pick-up, and bonding with a lead frame. As such, in order to prevent the scattering of chips in the course of dicing, adhesive tape is used. Although the adhesive tape should have large adhesion force enough to strongly hold chips from a dicing process until a drying process, the adhesion force thereof should be remarkably decreased in a pick-up process so that the chips can be safely transferred to a die bonding process.

Further, the chips, which are transferred to the die bonding process, are attached to the lead frame using a liquid epoxy adhesive in the die bonding process. However, in a package such as CSP (Chip Scale Packaging) or BGA (Ball Grid Array), requiring high density and high integration, since there is a need for a laminating technique in which dies are stacked four or more layers on the die attached to the upper surface of the lead frame, it is difficult to uniformly apply a liquid epoxy adhesive. Thus, due to an excess of or a lack of the adhesive, satisfactory adhesion is not realized. Ultimately, for multilayer die bonding, an adhesive and a bonding method should be improved.

In order to solve the problems, a die bonding adhesive tape, which can realize direct die bonding without the need for an additional adhesive application process upon die bonding via a die pick-up process after exhibiting a strong wafer holding function in a dicing process by forming an adhesive layer on the other surface of a wafer in advance, is disclosed in Korean Patent Laid-open Publication No. 10-2004-0030979 (hereinafter, referred to as the ‘first conventional technique’) and Korean Patent Laid-open Publication No. 10-2004-0029939 (hereinafter referred to as the ‘second conventional technique’).

FIGS. 1A and 1B illustrate the process of preparing the die bonding adhesive tape according to a first conventional technique, and FIGS. 2A and 2B illustrate the die bonding process using the die bonding adhesive tape of FIG. 1B. As illustrated in FIG. 1A, the adhesive tape according to the first conventional technique comprises a base substrate 2 and an adhesive layer 1 which is placed thereon and is composed of an epoxy resin, an epoxy resin curing agent, an acrylic acid ester copolymer, a general-purpose photopolymerizable low-molecular-weight compound, and a photopolymerization initiator. Further, as illustrated in FIG. 1B, a ring frame-bonding adhesive tape 3, which functions to attach a ring frame 5 for holding the adhesive layer 1 to the base substrate 2, is laminated on the upper edge of the adhesive layer 1.

As illustrated in FIG. 2A, such an adhesive layer 1 exhibits a wafer holding function upon wafer dicing, after which the UV curable adhesive component, among the components thereof, is cured upon exposure to UV light to thus decrease adhesion force to the base substrate 2. Accordingly, as illustrated in FIG. 2B, shortly after the adhesive layer 1 is separated, along with a die (chip) 4 from the base substrate 2 upon die pick-up, an adhesive layer-attached die (chip) 6 is placed on a lead frame (not shown) and heated to cure the epoxy resin contained in the adhesive layer 1 so as to manifest adhesion force, therefore resulting in a die 7 with the lead frame bonded thereto due to the adhesive layer, as seen in FIG. 2B.

FIGS. 3A to 3C illustrate the process of preparing the die bonding adhesive tape according to a second conventional technique, and FIGS. 4A and 4B illustrate the die bonding process using the die bonding adhesive tape of FIG. 3C. As illustrated in FIG. 3A, the adhesive tape according to the second conventional technique comprises a film structure including an adhesive film 8 prepared using a composition composed of an epoxy resin, an epoxy resin curing agent, an acrylic acid ester copolymer, and a filler, and a release film 9 for removably supporting the adhesive film. As illustrated in FIG. 3B, a base substrate structure, comprising a base substrate 2 and an adhesive layer 10 placed thereon and composed of an acrylic acid ester copolymer, a general-purpose photopolymerizable low-molecular-weight compound, and a photopolymerization initiator, is provided. As illustrated in FIG. 3C, after removal of the release film 9, the adhesive film 8 is laminated on the adhesive layer 10 of the base substrate structure.

As illustrated in FIG. 4A, such an adhesive tape exhibits a holding function upon dicing. Thereafter, when exposed to UV light, the adhesive layer 10 on the base substrate 2 is cured and thus the adhesion force to the adhesive film 8 is decreased. Further, as illustrated in FIG. 4B, upon die pick-up, an adhesive film-attached die 11 is separated from the cured adhesive layer 10 of the base substrate 2, immediately placed on a lead frame, and then heated to cure the epoxy resin contained in the adhesive film 8 so as to manifest adhesion force, thus resulting in a die 12 with the lead frame bonded thereto due to the adhesive film. In FIG. 4B, the reference numeral 5 designates the lead frame.

The die bonding adhesive tapes, according to the first and second conventional techniques, have something in common with each other in that the process of previously forming the adhesive layer or adhesive film on the other surface of the wafer is used, and thereby direct die bonding can be realized without the need for the process of applying an epoxy adhesive for additional die bonding after wafer dicing.

However, in the first conventional technique, since the UV curable adhesive component and the epoxy resin composition are mixed in a single-component type on the base substrate 2, an additional epoxy resin curing process must be performed for 30 min or longer, in addition to the UV irradiation process. Further, in the wafer dicing process, there is required an additional process of attaching the adhesive tape 3 for holding the ring frame around the adhesive layer. Furthermore, after the UV irradiation, in the die pick-up process for separating the adhesive layer having the die from the base substrate 2, the adhesive layer is difficult to efficiently separate from the base substrate 2 due to the adhesion force of the uncured epoxy resin composition of the adhesive layer. In particular, in the case of IC chips for memory semiconductors requiring high integration and high density, it is impossible to pick up a die, which is manufactured to be progressively thinner and larger, that is, a slim and large die, using the above adhesive tape.

Also, according to the second conventional technique, the adhesive film is attached to the upper surface of the UV curable adhesive layer on the base substrate 2 and is separated again from the adhesive layer through UV irradiation after completion of the dicing process, followed by conducting die pick-up and then direct die bonding. However, attributable to the transfer and diffusion of most of the UV curable low-molecular-weight compounds of the adhesive layer 10 toward the adhesive film 8 before UV irradiation, upon UV irradiation, the problem in which adhesion force is not remarkably decreased is caused. Moreover, in the case where the die has a size not smaller than 10 mm×10 mm and a thickness of 75 μm or less, the adhesion force between the adhesive film attached to the die and the adhesive layer on the base substrate is not remarkably decreased, and therefore the die pick-up process becomes difficult. Moreover, when the die pick-up process is forcefully attempted, the die may be undesirably broken by pick-up pressure. Further, this phenomenon also occurs in the first conventional technique. Thereby, the adhesive tapes disclosed in the first and second conventional techniques suffer because they have many limitations in picking up slim and large dies.

### SUMMARY OF THE INVENTION

Therefore, the present invention has been made keeping in mind the above problems occurring in the prior art, and an object of the present invention is to provide a die bonding adhesive tape, which functions to eliminate the need for an additional adhesive tape for attaching a ring frame, to decrease the curing time period upon die bonding, to essentially prevent the transfer and diffusion of low-molecular-weight compounds between an adhesive film and an adhesive layer on a base substrate to thus exhibit excellent pick-up performance when picking up a die, and to easily separate an adhesive film having a die from an adhesive layer on a base substrate when picking up slim and large dies.

In order to accomplish the above object, the present invention provides a die bonding adhesive tape, which comprises a base substrate and an adhesive layer formed on the base substrate, has a structure in which a core film having a die bonding adhesive film attached thereto is bonded onto the adhesive layer, and is capable of realizing direct die bonding via dicing and then die pick-up in a state of being mounted on a wafer.

In the present invention, as the base substrate of the adhesive tape, a transparent film which transmits UV light may be used. Examples of the transparent film include a polyethylene film, a polypropylene film, a polybutene film, a polybutadiene film, a polyvinyl chloride film, a polyethylene copolymer film, a polyurethane film, crosslinked films thereof, combined films thereof, and laminates thereof.

The adhesive layer, which is provided on the base substrate, does not include a UV curable component. Although acryl-, polyester-, urethane-, silicone-, rubber-based adhesives and other general-purpose adhesives may be used, the use of an acrylic adhesive is preferable in the present invention. The base substrate has surface tension of 40 dyne/cm or more, preferably 55 dyne/cm or more, and more preferably 75 dyne/cm or more, and thus the adhesive layer on the base substrate can exhibit good adhesion force to the base substrate. As such, the base substrate having such a high surface tension may be obtained by subjecting the surface of the substrate to corona treatment. The thickness of the base substrate ranges from 30 to 250 μm, preferably from 50 to 200 μm, and more preferably from 70 to 150 μm.

The adhesive tape of the present invention may be obtained by applying an adhesive composition composed of the above components on the base substrate through a known process using a knife coater or a gravure coater and then drying it to thus form an adhesive layer. This adhesive layer is 2˜30 μm thick.

In the present invention, the core film is a thermoplastic film 5˜100 μm thick. Although the material thereof is not particularly limited, it should be a transparent film transmitting UV light and having a difference in surface tension between the two surfaces thereof amounting to 5 dyne/cm or more, preferably 30 dyne/cm or more, and more preferably 70 dyne/cm or more. Further, the first surface of the core film which is attached to the adhesive film preferably has surface tension of 25˜40 dyne/cm, whereas the second surface of the core film, which is attached to the adhesive layer on the base substrate, preferably has surface tension of 45˜110 dyne/cm. In order to increase the surface tension of the surface of the core film which is attached to the adhesive layer, corona surface treatment may be performed. In addition, for the above purpose, a core film produced through a co-extrusion process may be used, and the core film thus produced is structured so that both surfaces thereof have very different layers from each other. In this way, since the core film has a difference in surface tension between the two surfaces thereof, it is essentially possible to separate the adhesive film having the die from the surface of the core film having low surface tension when picking up a die. However, in the case where the surface tension of the surface of the core film to be attached to the adhesive film is too low, the adhesion force between the adhesive film and the core film is weakened in the course of dicing, and thus the die may be scattered from the core film along with the adhesive film. Therefore, appropriate surface tension is required, which is achieved by adding an adhesive component to the composition for the adhesive film. Such a component comprises a low-molecular-weight adhesive component having tackiness, but the present invention is not limited thereto. Examples thereof include a UV curable low-molecular-weight compound, a petroleum-based rosin low-molecular-weight compound, liquid epoxy resin and acryl resin having a molecular weight from 1,000 to 8,000, and a reactive rubber compound.

Since the adhesive film of the present invention contains the UV curable low-molecular-weight compound, adhesion force to the core film may be sufficiently maintained before UV irradiation. Such adhesion force is 5˜150 gf/25 mm, and preferably 30˜100 gf/25 mm. After the UV irradiation for die pick-up, the adhesion force is preferably drastically decreased such that the adhesive film having the die may be easily separated from the core film. Here, the adhesion force is preferably 50 gf/25 mm or less, and more preferably 30 gf/25 mm or less.

On the other hand, the surface of the core film which is attached to the adhesive layer on the base substrate has adhesion force of 150˜800 gf/25 mm, and preferably 200˜500 gf/25 mm. Further, although the surface of the core film attached to the adhesive layer should have adhesion force as high as possible, the magnitude of the adhesion force should be suitable for easily removing the base substrate from the ring frame after the completion of the die bonding process.

The adhesive film of the present invention is composed mainly of a high-molecular-weight acrylic copolymer, a butadiene copolymer, and a thermosetting resin, and further includes a UV curable low-molecular-weight compound and a photoinitiator. As such, the molecular weight of the acrylic copolymer is at least one million, and preferably ranges from two million to three million. In the preparation of the adhesive film, the high-molecular-weight acrylic copolymer functions to enable the formation of a ductile film. Examples of the acrylic copolymer include acrylic rubbers, such as copolymers of acrylic acid ester or methacrylic acid ester and acrylonitrile. In the present invention, the acrylic copolymer is mixed with the butadiene copolymer acting as an organic filler, which is effective in improving flexibility at low temperatures and realizing low elastic modulus, thereby minimizing the generation of stress on a slim and large die in the course of compression upon die bonding. The adhesive film of the present invention may be a film containing a thermosetting resin, in particular, an adhesive film composed mainly of epoxy resin as the thermosetting resin. Further, the epoxy resin in the adhesive film of the present invention may be used without particular limitation as long as it is cured to thus exhibit adhesion force. For a curing reaction, the epoxy resin preferably has at least two functional groups and a molecular weight less than 8000, and examples thereof include bisphenol A type epoxy resin or novolac type epoxy resin, such as phenol novolac type epoxy resin or cresol novolac type epoxy resin. In particular, novolac type epoxy resin is preferably used because it has high heat resistance.

As the curing agent in the adhesive film of the present invention, any curing agent may be used without particular limitation as long as it functions to cure the epoxy resin. From the point of view of high heat resistance, the use of a novolac type phenol resin is preferable. Further, in order to accelerate the curing of the epoxy resin, a curing accelerator may be used, and examples thereof include imidazoles and amines.

In the present invention, the adhesive film, which is prepared using the above-mentioned components, is not directly bonded to the adhesive layer on the base substrate but is bonded to the adhesive layer on the base substrate using the core film, having a difference in surface tension between the two surfaces thereof. The adhesive film bonded with the core film plays a role in exhibiting adhesion force suitable for preventing the scattering of dies upon actual dicing, and the adhesive layer on the base substrate is responsible for supporting the core film and the adhesive film provided thereon by strong adhesion force to the core film. Upon die pick-up after the dicing process, the UV curable low-molecular-weight compound in the adhesive film is cured by UV irradiation, such that the adhesion force between the adhesive film and the core film is preferably remarkably decreased, thus making it possible to easily separate the adhesive film having the die from the core film by the pressure upon die pick-up, which may be easily applied to slim and large dies.

### BRIEF DESCRIPTION OF THE DRAWINGS

FIGS. 1A and 1B illustrate the process of preparing a die bonding adhesive tape according to a first conventional technique;

FIGS. 2A and 2B illustrate the die bonding process using the die bonding adhesive tape of FIG. 1B;

FIGS. 3A to 3C illustrate the process of preparing a die bonding adhesive tape according to a second conventional technique;

FIGS. 4A and 4B illustrate the die bonding process using the die bonding adhesive tape of FIG. 3C;

FIGS. 5A to 5C illustrate the process of preparing a die bonding adhesive tape according to the present invention; and

FIGS. 6A and 6B illustrate the die bonding process using the die bonding adhesive tape of FIG. 5C.

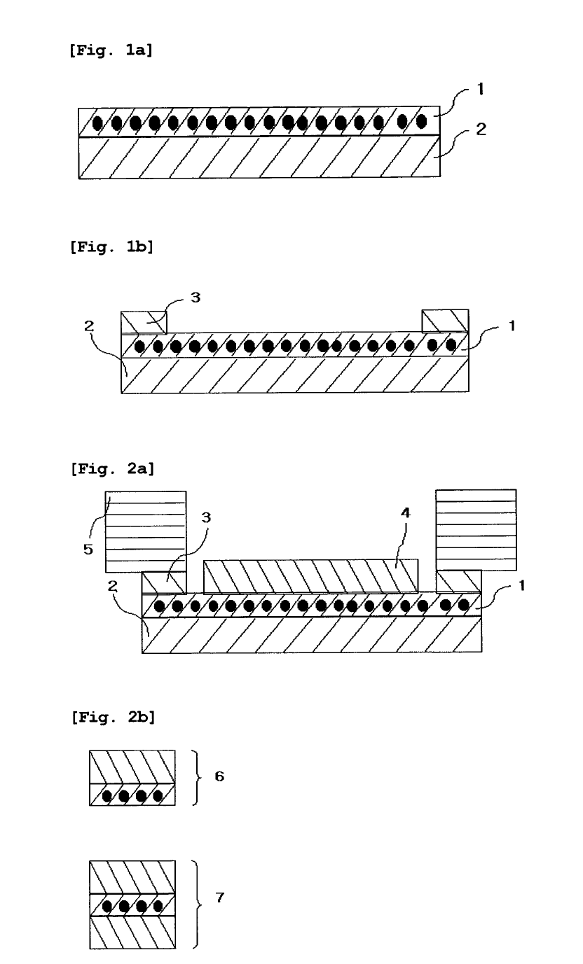

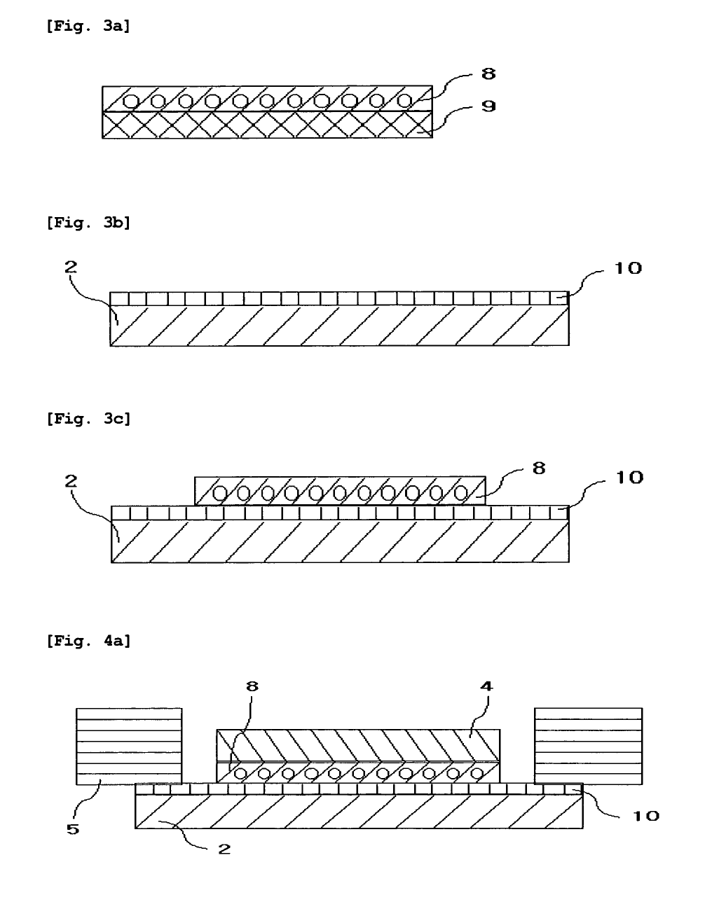

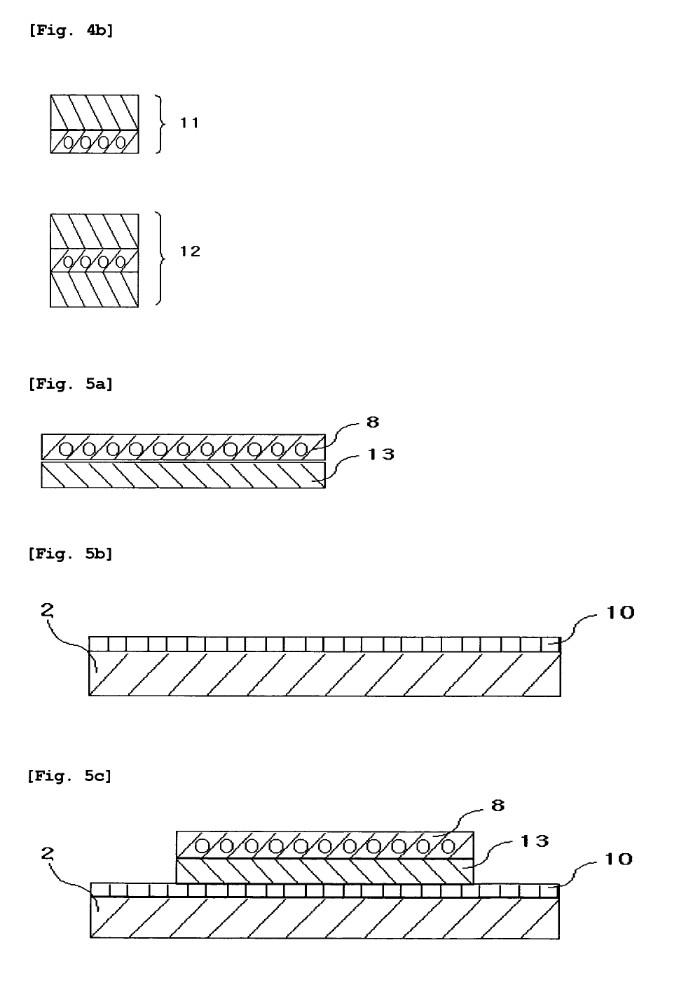

### DESCRIPTION OF THE PREFERRED EMBODIMENTS

Hereinafter, a detailed description will be given of various embodiments of the die bonding adhesive tape of the present invention and a method of manufacturing an adhesive film thereof, with reference to the appended drawing.

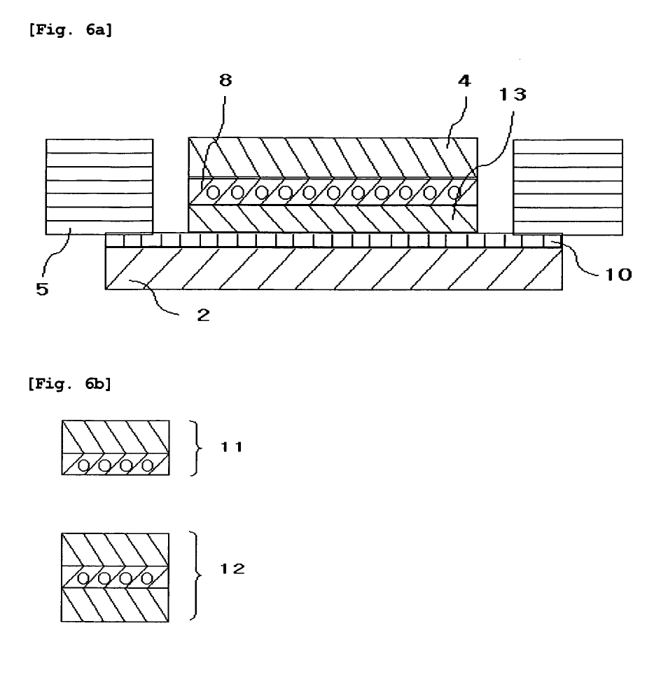

FIGS. 5A to 5C illustrate the process of preparing the die bonding adhesive tape of the present invention, and FIGS. 6A and 6B illustrate the die bonding process using the die bonding adhesive tape of FIG. 5C. In FIG. 5A, the reference numeral 8 designates an adhesive film, which is composed mainly of a high-molecular-weight acrylic copolymer, a butadiene copolymer, an epoxy resin, and an epoxy resin curing agent, and further includes a UV curable low-molecular-weight compound and a photoinitiator. As such, the acrylic copolymer has a molecular weight of at least one million, and preferably ranges from two million to three million. The high-molecular-weight acrylic copolymer, which functions to confer ductility to the adhesive film to be prepared, constitutes a base resin of the film, and is exemplified by acrylic rubbers, such as copolymers of acrylic acid ester or methacrylic acid ester and acrylonitrile.

In order to increase the Tg of the acrylic copolymer, an oligomer having a functional group such as a hydroxyl group or a carboxylic group, for example, oligoester acrylate or polyester acrylate, may be added. As the curing agent, toluene diisocyanate may be used. The oligomer is used in an amount of 1˜30 parts by weight, and preferably 5˜15 parts by weight, based on 100 parts by weight of the acrylic copolymer, and toluene diisocyanate is used in an amount of 0.1˜15 parts by weight, and preferably 2˜8 parts by weight, based on 100 parts by weight of the total amount of the oligomer. Examples of the butadiene copolymer include an acrylonitrile butadiene copolymer, a styrene butadiene copolymer, and acrylonitrile butadiene. As such, polybutadiene may be used alone. Such a butadiene copolymer, which is mixed as an organic filler to increase flexibility at low temperatures and realize low elastic modulus, is used in an amount of 0.1˜50 parts by weight, preferably 1˜20 parts by weight, and more preferably 5˜10 parts by weight. This component is effective in minimizing the generation of stress on a slim and large die in the course of compression upon die bonding. However, when the amount of the butadiene copolymer exceeds 50 parts by weight, the resulting adhesive film has excessive ductility and thus may be easily deformed upon die bonding. On the other hand, when the amount of the butadiene copolymer is less than 1 part by weight, a low elastic modulus is not realized.

The epoxy resin may be used without particular limitation as long as it is cured to thus exhibit adhesion force, and should have at least two functional groups and a molecular weight less than 8000 in order to be cured. For example, bisphenol A type epoxy resin or novolac type epoxy resin, such as phenol novolac type epoxy resin or cresol novolac type epoxy resin may be used. Preferably, useful is novolac type epoxy resin, which has high heat resistance.

Regarding the mixing proportion of the adhesive composition for preparation of the adhesive film, based on 100 parts by weight of the total amount of the acrylic copolymer and the butadiene copolymer, the epoxy resin is used in an amount of 5˜80 parts by weight and preferably 10˜50 parts by weight. However, when the epoxy resin is used in an amount exceeding 80 parts by weight, brittleness is enhanced upon the formation of the adhesive film, undesirably causing a film breakage phenomenon. On the other hand, when the amount is less than 5 parts by weight, the epoxy resin does not exhibit adhesive performance.

The curing agent may be used without particular limitation as long as it functions to cure the epoxy resin. From the point of view of high heat resistance, novolac type phenol resin is preferably used. The phenol resin, which serves as the curing agent of the epoxy resin, is used in an amount of 10˜50 parts by weight and preferably 20˜40 parts by weight, based on 100 parts by weight of the epoxy resin. Further, in order to accelerate the curing reaction of the epoxy resin, a curing accelerator, for example, imidazole or amine, may be used. The curing accelerator is used in an amount of 0.1˜10 parts by weight, and preferably 1˜5 parts by weight, based on 100 parts by weight of the total amount of the epoxy resin and the curing agent. Otherwise, when the curing accelerator is used in an amount exceeding 10 parts by weight, the curing of the epoxy resin is excessively accelerated in the course of preparation of the adhesive film, and is undesirably brittle, therefore making it impossible to form a desired adhesive film. On the other hand, when the amount is less than 1 part by weight, the adhesive film should be additionally cured upon die bonding due to the slow curing rate of the epoxy resin.

The UV curable low-molecular-weight compound has at least one double bond in the molecule thereof, and is exemplified by low-molecular-weight compounds, disclosed in Japanese Patent Laid-open Publication Nos. 1985-196956 and 1985-223139. Examples thereof include acrylate compounds, such as trimethylolpropane triacrylate, tetramethylol methane tetraacrylate, or pentaerythritol triacrylate. Such a UV curable low-molecular-weight compound is used in an amount of 0.5˜50 parts by weight, preferably 1˜30 parts by weight, and more preferably 5˜15 parts by weight, based on 100 parts by weight of the total amount of the adhesive composition for preparation of the adhesive film. Since the UV curable low-molecular-weight compound reacts only upon UV irradiation to begin to be cured, it functions to provide the adhesive properties to the adhesive film in the adhesive film preparation process or dicing process. Upon UV irradiation for die pick-up, the above compound is sufficiently cured, such that the adhesion force between the adhesive film and the core film is drastically decreased, thereby improving die pick-up performance. When the amount of the UV curable low-molecular-weight compound exceeds 50 parts by weight, flexibility is excessively increased, undesirably deteriorating the properties of the adhesive film. On the other hand, when the amount is less than 0.5 parts by weight, no curing reaction occurs upon UV irradiation.

Further, in order to accelerate the curing of the UV curable low-molecular-weight compound, a photoinitiator may be used. Examples of the photoinitiator include benzophenone, acetophenone, dibenzyl, diacetyl, diphenyl sulfide, and azobisisobutyronitrile. The photoinitiator is used in an amount of 0.5˜15 parts by weight, preferably 1.0˜10 parts by weight, and more preferably 1.5˜4 parts by weight, based on 100 parts by weight of the total amount of the UV curable low-molecular-weight compound.

For preparation of the above adhesive composition into the adhesive film, there are required processes of mixing the composition with a solvent to thus make a varnish form, which is then applied on an additional base substrate and dried.

In FIG. 5A, the reference numeral 13 designates a core film having a difference in surface tension between both surfaces thereof. In order to form such a core film, one surface of the core film may be subjected to corona treatment, or a co-extrusion process may be applied such that layers different from each other are respectively formed on the two surfaces thereof. The core film 13 is used as a base substrate for preparation of the adhesive film 8. Thus, the adhesive mixture is applied on the surface of the core film 13 opposite the surface subjected to corona treatment, and is then dried, resulting in the adhesive film 8 bonded with the core film 13. As such, the adhesive mixture, obtained by adding the solvent to the adhesive composition, stirring the mixture, and then deaerating it in a vacuum, is applied on the core film. As the solvent, an appropriate mixture of ethyl acetate, toluene, and methylethylketone is preferably used. The drying process is performed at 70˜130° C. for 60˜300 sec. If the drying process is performed at too high a temperature for a long time period, the curing of the epoxy resin contained in the adhesive mixture is excessively accelerated, and thus the brittleness of the dried film is increased. A consequence of the increase in brittleness is low adhesive performance of the adhesive film 8. In particular, the adhesive film 8 may be broken on the core film 13.

As mentioned above, the adhesive film 8 is prepared in such a manner that the adhesive composition is applied in the form of a film on the surface of the core film 13, which serves as a base substrate thereof and has low surface tension. The adhesive film 8 has a thickness ranging from 5 to 80 μm and preferably from 10 to 40 μm.

The core film 13, which is 5˜100 μm thick, is a thermoplastic film, but the present invention is not limited thereto. Preferably, the above film is a transparent film which transmits UV light. Further, the difference in surface tension between the two surfaces of the core film is 5 dyne/cm or more, preferably 30 dyne/cm or more, and more preferably 70 dyne/cm or more. The first surface of the core film 13, which is attached to the adhesive film 8, has surface tension of 25˜40 dyne/cm, while the second surface of the core film 13, which is attached to the adhesive layer on the base substrate, has surface tension of 45˜110 dyne/cm. Moreover, with the goal of increasing the surface tension of the surface of the core film 13 to be attached to the adhesive layer, this surface is preferably subjected to corona treatment. In addition, for this purpose, a core film produced through a co-extrusion process may be used, and the core film thus produced is structured so that the two surfaces thereof have layers that are very different from each other. A consequence of the difference in surface tension between the two surfaces of the core film is separation of the adhesive film 8 having the die from the surface of the core film 13 having low surface tension upon die pick-up. However, in the case where the surface tension of the surface of the core film 13 to be attached to the adhesive film 8 is too low, adhesion force between the adhesive film 8 and the core film 13 is weakened in the course of dicing and thus dies may be scattered along with the adhesive film 8 from the core film 13. Therefore, appropriate surface tension should be maintained. To this end, an adhesive component should be contained in the composition for the adhesive film 8. Such a component is a low-molecular-weight adhesive component having tackiness, but the present invention is not limited thereto. Examples thereof include a UV curable low-molecular-weight compound, a petroleum-based rosin low-molecular-weight compound, liquid epoxy resin and acryl resin having a molecular weight from 1,000 to 8,000, and a reactive rubber compound.

The adhesive film 8 of the present invention contains the UV curable low-molecular-weight compound, and therefore can exhibit sufficient adhesion force to the core film before UV irradiation. Suitable adhesion force is 5˜150 gf/25 mm, and preferably 30˜100 gf/25 mm.

After the UV irradiation for die pick-up, the adhesion force is drastically decreased such that the adhesive film 8 bonded with the die may be easily separated from the core film 13. Such adhesion force is 50 gf/25 mm or less, preferably 30 gf/25 mm or less, and more preferably 1 gf/25 mm or less. In particular, in the case of a slim die 75 μm thick or less, adhesion force between the base substrate and the adhesive film 8 having the die should be very low when picking up a die. On the other hand, when the adhesion force exceeds 50 gf/25 mm, the die may be easily bent by the pressure of picking up the die. At worst, the die may be broken. Further, if the die has a size not smaller than 10 mm×10 mm while maintaining the slim form, the above-mentioned undesirable phenomenon may occur readily.

In the present invention, using the core film 13, the low-molecular-weight compound of the adhesive layer on the base substrate, which acts to increase adhesion force, is essentially prevented from being transferred and diffused. Further, using the UV curable low-molecular-weight compounds among the components of the adhesive film 8, upon UV irradiation, adhesion force to the core film 13 may be remarkably decreased so as to enable easy separation. Thereby, conventional problems which are caused in a slim and large die having a thickness of 75 μm or less and a size not smaller than 10 mm×10 mm may be overcome. As well as a slim and large die, it is possible to pick up a general-purpose die having a thickness of 75 μm or more and a size not larger than 10 mm×10 mm. Accordingly, the die bonding adhesive tape of the present invention is not limited in use thereof only to a slim and large die.

In FIG. 5B, the reference numeral 2 designates a base substrate of the adhesive tape, which is a transparent film which transmits UV light. Examples thereof include a polyethylene film, a polypropylene film, a polybutene film, a polybutadiene film, a polyvinyl chloride film, a polyethylene copolymer film, and a polyurethane film, which may be used alone or may be realized in combined extruded films thereof. Moreover, the surface of the base substrate may be subjected to corona treatment in order to increase surface tension.

In FIG. 5B, the reference numeral 10 designates an adhesive layer, which may be formed using a general-purpose acrylic adhesive. Such an adhesive is applied on a base substrate 2 and dried to thus form an adhesive layer 10, resulting in the adhesive tape. The surface of the core film 13, which is attached to the adhesive layer 10 on the base substrate 2, has adhesion force of 150˜800 gf/25 mm and preferably 200˜500 gf/25 mm. Further, although the surface of the core film 13 attached to the adhesive layer 10 should have adhesion force as high as possible, the magnitude of the adhesion force should be suitable for easily removing the base substrate 2 from a ring frame after completion of a die bonding process. The adhesive tape thus prepared is attached to the adhesive film 8, thus completing the die bonding adhesive tape as shown in FIG. 5C. As illustrated in FIG. 6A, the die bonding adhesive tape thus obtained is held on a ring frame 5 for dicing, and is then mounted on the other surface of a wafer at 20˜80° C. for wafer dicing.

Thereafter, the wafer is subjected to dicing into individual dies along with the die bonding adhesive tape. For subsequent die pick-up, UV light is radiated onto the adhesive tape having the die. In the present invention, UV light having a central wavelength of about 365 nm is applied at an illuminance of 2˜500 mW/cm² for 0.1˜150 sec. After the UV irradiation, individual dies are subjected to pick-up, and thus a die 11 having only the adhesive film 8 attached thereto is obtained, consequently producing a die 12 with the lead frame bonded thereto due to the adhesive film, as shown in FIG. 6B.

A better understanding of the present invention may be obtained in light of the following examples, which are set forth to illustrate, but are not to be construed to limit the present invention. In the following description, the term “parts” indicates parts by weight. Further, the description of a tensile strength measuring apparatus, a UV irradiation apparatus, and an adhesion force measuring apparatus are given in the corresponding result section.

### PREPARATIVE EXAMPLE 1

Preparation of Die Bonding Adhesive Film 1

A composition for a die bonding adhesive film, composed of an epoxy resin, a phenol resin, and an acrylic adhesive solution, was added with an acrylic curing agent and a curing accelerator for curing the epoxy resin. As such, the epoxy resin and the phenol resin were mixed at a ratio of 5:3 and stirred for 30 min, after which the stirred solution thus obtained and the acrylic adhesive were mixed at a ratio of 15:45 and stirred for 3 hours. Subsequently, the acrylic curing agent and the epoxy curing accelerator were added thereto, and then a stirring process was performed for an additional 30 min, thus obtaining the die bonding adhesive film 1. As shown in Composition Table 1 below, respective components were used after being diluted in an organic solvent at a predetermined proportion.

### PREPARATIVE EXAMPLE 2

Preparation of Die Bonding Adhesive Film 2

A die bonding adhesive film was prepared in the same manner as in Preparative Example 1, after which a UV curable low-molecular-weight compound was added to strengthen adhesion force and a stirring process was performed for 30 min, thereby obtaining the die bonding adhesive film 2.

### PREPARATIVE EXAMPLE 3

Preparation of Die Bonding Adhesive Film 3

A die bonding adhesive film was prepared in the same manner as in Preparative Example 2, after which a photoinitiator was added for UV curing and a stirring process was performed for 30 min, thereby obtaining the die bonding adhesive film 3.

### PREPARATIVE EXAMPLE 4

Preparation of Die Bonding Adhesive Film 2

A die bonding adhesive film was prepared in the same manner as in Preparative Example 3, after which a larger amount of photoinitiator was added to increase the degree of curing by UV irradiation, and then a stirring process was performed for 30 min, thereby obtaining the die bonding adhesive film 4.

The stirred solution of Preparative Examples 1 to 4 was applied to a thickness of 20 μm on the non-corona treated surface of a cast polypropylene film 40 μm thick as a base substrate thereof, thus forming an adhesive layer. Subsequently, on the adhesive layer, a polyethylene terephthalate film 40 μm was laminated in order to protect the adhesive layer.

COMPOSITION TABLE 1
Compositions of Preparative Examples 1 to 4

(unit: wt parts)

| | P. | P. | P. | P. |
|---|---|---|---|---|
| Components | Ex. 1 | Ex. 2 | Ex. 3 | Ex. 4 |
| Epoxy Resin | 33.7 | 26.5 | 24 | 22.9 |
| Phenol Resin | 20.2 | 15.9 | 14.4 | 13.7 |
| Acrylic Adhesive | 40.4 | 31.8 | 28.8 | 27.5 |
| Acrylic Curing Agent | 5.4 | 4.3 | 3.8 | 3.7 |
| Butadiene Copolymer | 0 | 0 | 5.0 | 10.0 |
| Photoinitiator | 0 | 0 | 9.6 | 13.7 |
| UV Curable Low-Molecular-Weight | 0 | 21.2 | 19.2 | 18.3 |
| Compound | | | | |
| Epoxy Curing Accelerator | 0.3 | 0.3 | 0.2 | 0.2 |

In Table 1, the epoxy resin is cresol novolac type epoxy resin, having a softening point of 68˜72° C. and 200˜212 equivalents, and is used in the form of a 50% solution using methylethylketone as a solvent. The phenol resin is the same type as the above epoxy resin and is also used in the form of a 50% solution.

An acrylic copolymer having a molecular weight of one million is used. In order to cure the phenol resin, the epoxy resin, and the acrylic copolymer, toluene diisocyanate is used. The butadiene copolymer is an acrylonitrile butadiene copolymer having a molecular weight of four hundred thousand and 35% acrylonitrile. The photoinitiator is 2-hydroxy-2-methylpropiophenone, and the UV curable low-molecular-weight compound is pentaerythritol triacrylate. The epoxy curing accelerator is 1-cyanoethyl-2-phenylimidazole, having a melting point of 105˜108° C.

### EXAMPLE 1

Measurement of Peel Strength between Base Substrate (Cast Polypropylene Film) and Die Bonding Adhesive Film

The peel strength between the die bonding adhesive film of Preparative Examples 1 to 4 and the cast polypropylene film serving both as a core film and as a base substrate of the adhesive film was measured. To this end, a film A having high adhesion force, cut to a sufficiently large size, was fitted to the upper portion of an adhesion force measuring apparatus, and the die bonding adhesive film and the cast polypropylene film serving as a base substrate thereof were cut to a width of 25 mm and then provided to bring the upper surface of the die bonding adhesive film into contact with the film A, followed by performing a lamination process under pressure of 2 kgf. Thereafter, the cast polypropylene film (core film) alone was removed at a rate of 300 mm/min. To evaluate the effect of the photoinitiator, the strength was measured after UV irradiation for 1 min. The adhesion force measuring apparatus, available from Shimpo, had a maximum load of 5.0 Kg, 49.03 N.

In Preparative Examples 1 and 2, omitting the use of the photoinitiator, UV irradiation was not performed.

RESULT TABLE 1
(unit: gf/25 mm)

| | Peel Strength | Peel Strength |
|---|---|---|
| Sample | Before UV Irradiation | After UV Irradiation |
| P. Ex. 1 | 1 | |
| P. Ex. 2 | 35 | |
| P. Ex. 3 | 35 | 2 |
| P. Ex. 4 | 35 | 2 |

As is apparent from Result Table 1, in which die pick-up performance is evaluated depending on UV irradiation, it can be seen that adhesion force between the adhesive film and the core film was drastically decreased through the UV irradiation. Thereby, performance when picking up a slim and large die is expected to increase.

### EXAMPLE 2

Measurement of Adhesion Force between Die Bonding Adhesive Film and Wafer

The adhesion force between the die bonding adhesive film of Preparative Examples 1 to 4 and the wafer was measured. To this end, an adhesive film having relatively good adhesion force and a small radius of curvature was laminated on the die bonding adhesive film, and the die bonding adhesive film was cut to a width of 25 mm and attached to the wafer heated to 60° C., and then UV irradiation was conducted for 1 min, and thus the peel strength was measured.

RESULT TABLE 2
(unit: gf/25 mm)

| | Peel Strength | Peel Strength |
|---|---|---|
| Sample | Before UV Irradiation | After UV Irradiation |
| P. Ex. 1 | 2 | 2 |
| P. Ex. 2 | 54 | 54 |
| P. Ex. 3 | 55 | 81 |
| P. Ex. 4 | 57 | 77 |

As is apparent from Result Table 2, in which the adhesion force between the wafer and the adhesive film is evaluated, it can be seen that the adhesion force between the adhesive film and the wafer was increased while the adhesion force between the adhesive film and the core film was drastically decreased by the UV irradiation.

### EXAMPLE 3

Measurement of Tensile Strength of Die Bonding Adhesive Film

The tensile strength of the die bonding adhesive film of Preparative Examples 1 to 4 was measured. To this end, according to the standard method of ASTM, using a tensile strength measuring apparatus available from Kyungsung Testing Machine Co. Ltd., Korea, having a maximum load of 50 kg, 490 N, measurement was conducted via a process of pulling a sample having a width of 10 mm, a gauge distance of 40 mm, and a thickness of 20 μm, at a rate of 300 mm/min in a perpendicular direction.

RESULT TABLE 3

| Sample | Tensile Strength (N/mm²) | Max. Load (N) |
|---|---|---|
| P. Ex. 1 | 1.55 | 0.31 |
| P. Ex. 2 | 0.50 | 0.10 |
| P. Ex. 3 | 1.35 | 0.27 |
| P. Ex. 4 | 1.41 | 0.28 |

As is apparent from Result Table 3, in which the mechanical properties of the adhesive film are evaluated, it can be seen that the tensile strength of the adhesive film was decreased when the UV curable low-molecular-weight compound was not cured by the photoinitiator. Conversely, upon curing using the photoinitiator, tensile strength can be seen to be maintained.

### EXAMPLE 4

Measurement of Shear Strength of Die Bonding Adhesive Film

The shear strength of the die bonding adhesive film of Preparative Examples 1 to 4 was measured. To this end, a UTM available from Kyungsung Testing Machine Co. Ltd., Korea, was used. Further, the die bonding adhesive film cut to a size of 25 mm×35 mm was laminated on the polyethyleneterephthalate film 200 μm thick cut to a size of 150 mm (length)×40 mm (width), and then the upper surface of the adhesive film was attached to SUS, followed by performing heating to 170° C., compression for 1 sec, and pulling in a perpendicular direction, and thus the strength was measured.

RESULT TABLE 4

| Sample | Shear Strength (N) |
|---|---|
| P. Ex. 1 | 8.1 |
| P. Ex. 2 | 6.5 |
| P. Ex. 3 | 7.2 |
| P. Ex. 4 | 7.3 |

As is apparent from Result Table 4, in which whether compression is good or not is evaluated under initial compression conditions upon die bonding, it can be seen that the degree of compression was determined to be good in all Preparative Examples 1 to 4.

### PREPARATIVE EXAMPLE 5

Preparation of Dicing Film 1

On a polyvinyl chloride film 85 μm thick serving as a base substrate, 100 parts of an acrylic adhesive solution and 8 parts of an acrylic curing agent were mixed and then applied to a thickness of 10 μm. A drying process was performed at 78° C. for 2 min, and then an aging process was conducted at 40° C. for 48 hours, thereby obtaining a dicing film 1.

### PREPARATIVE EXAMPLE 6

Preparation of Dicing Film 2

50 parts of an ethylene vinyl acetate resin, 25 parts of a low-density polyethylene resin, and 30 parts of a polypropylene resin were mixed to prepare a film having a thickness of 100 μm in order to serve as a base substrate. On the film thus prepared, a stirred solution comprising 100 parts of an acrylic adhesive solution and 3 parts of an acrylic curing agent was applied, dried at 78° C. for 2 min, and then aged at 40° C. for 48 hours, thereby obtaining a dicing film 2.

### PREPARATIVE EXAMPLE 7

Preparation of Dicing Film 3

50 parts of an ethylene vinyl acetate resin, 25 parts of a low-density polyethylene resin, and 30 parts of a polypropylene resin were mixed to prepare a film having a thickness of 100 μm in order to serve as a base substrate. On the film thus prepared, a stirred solution comprising an acrylic copolymer adhesive solution a, an acrylic copolymer adhesive solution b, a photoinitiator, an acrylic curing agent, and a UV curable low-molecular-weight compound was applied, dried at 78° C. for 2 min, and then aged at 40° C. for 48 hours, thereby obtaining a dicing film 3.

The die bonding adhesive film of Preparative Examples 1 to 4 was laminated on the dicing film of Preparative Examples 5 to 7 under pressure of 40 kg. As such, using a circular cutting and film laminating apparatus, the die bonding adhesive film having a diameter of 220 mm was laminated to be positioned on the center of the dicing film having a diameter of 270 mm, and the two films were cut to a circular shape. The surface of the laminated film was protected by the polyethyleneterephthalate film provided on the die bonding adhesive film. The cast polypropylene film, which was the base substrate of the die bonding adhesive film, was laminated and thus brought into contact with the dicing film.

### EXAMPLE 5

Measurement of Peel Strength between Die Bonding Adhesive Film on Dicing Film through Direct Lamination (Omission of Cast Polypropylene Film as Core Film)

The die bonding adhesive film of Preparative Examples 1 to 4 was directly laminated on the upper surface of the dicing film of Preparative Examples 5 to 7. As such, the cast polypropylene film, which was the base substrate of the die bonding adhesive film, was omitted, such that the above two films were brought into direct contact with each other. Further, an adhesive film having relatively good adhesion force and a small radius of curvature was laminated on the die bonding adhesive film and cut to 25 mm, the dicing film was held to a predetermined base substrate, and then the upper die bonding adhesive film was stripped at a rate of 300 mm/min to thus determine peel strength.

Result 5

Even though the UV curable low-molecular-weight compound contained in the adhesive layer of the base substrate was cured by UV irradiation, normal stripping was not realized due to high adhesion force. From this, die pick-up performance was judged depending on the presence of the core film. In the absence of the core film, it could be seen that the die bonding adhesive film was difficult to separate from the dicing film.

### EXAMPLE 6

Measurement of Peel Strength between Dicing Film and Cast Polypropylene Film (Core Film)

On the dicing film of Preparative Examples 5 to 7, the cast polypropylene film (core film), which was the base substrate of the die bonding adhesive film, was laminated, and thus the peel strength was measured. The cast polypropylene film was cut to a width of 25 mm, laminated on the dicing film of Preparative Examples 5 to 7, and was then stripped at a rate of 300 mm/min, therefore determining peel strength. Thereafter, the dicing film of Preparative Examples 5 to 7 was cut to a width of 25 mm, laminated on the cast polypropylene film, and then stripped as mentioned above, also measuring peel strength. Such measurement procedures were repeated several times and the results thereof were averaged. That is, the values when stripping the dicing film and when stripping the cast polypropylene film were averaged, respectively. As such, it is noted that the measurement result is changed depending on whether the cast polypropylene film is subjected to corona surface treatment.

RESULT TABLE 6
(unit: gf/25 mm)

| | | UV | Peel |
|---|---|---|---|
| Sample | Film Lamination Structure | Irradiation | Strength |
| P. Ex. 5 | Lamination on Corona Treated Surface | No | 218 |
| | Lamination on Non-corona treated Surface | No | 31 |
| P. Ex. 6 | Lamination on Corona Treated Surface | No | 224 |
| | Lamination on Non-corona treated Surface | No | 40 |
| P. Ex. 7 | Lamination on Corona Treated Surface | No | 167 |
| | Lamination on Non-corona treated Surface | No | 31 |
| | Lamination on Corona Treated Surface | Yes | 3 |
| | Lamination on Non-corona treated Surface | Yes | 0 |

As is apparent from Result Table 6, in which the adhesion force to the dicing film is evaluated via surface treatment of the core film, it can be seen that the adhesion force varies depending on the surface treatment. In the case of Preparative Example 7, the adhesion force can be seen to be decreased by UV curing. Thus, for the function of the dicing film as a base substrate, it should be bonded to the corona treated surface of the core film having high surface tension, and the adhesive layer on the dicing film should not contain the UV curable low-molecular-weight compound.

### EXAMPLE 7

Evaluation of Dicing and Pick-Up Performance

Apparatus: NB200

Blade: Disco (Japan)

Sawing Speed: 120 mm/sec

Blade RPM: 40,000 RPM

Sawing Depth: 50 μm (60 μm, 85 μm)

Die Size: 16×10 (5×5, 10×6, 10×6)

Cooling Water: 1.2/min

Wafer: Silicon wafer having a polished back surface and having a thickness of 75 μm

RESULT TABLE 7

| | Pick-up | Lamination | Scattering of |
|---|---|---|---|
| Sample | Performance | State | Chips |
| (1) P. Ex. 1/P. Ex. 5 | ◯ | X | X |
| (2) P. Ex. 1/P. Ex. 6 | ◯ | X | X |
| (3) P. Ex. 1/P. Ex. 7 | X | X | X |
| (4) P. Ex. 2/P. Ex. 5 | □ | ◯ | ◯ |
| (5) P. Ex. 2/P. Ex. 6 | □ | ◯ | ◯ |
| (6) P. Ex. 2/P. Ex. 7 | X | ◯ | ◯ |
| (7) P. Ex. 3/P. Ex. 5 | ◯ | ◯ | ◯ |
| (8) P. Ex. 3/P. Ex. 6 | ◯ | ◯ | ◯ |
| (9) P. Ex. 3/P. Ex. 7 | X | ◯ | ◯ |
| (10) P. Ex. 4/P. Ex. 5 | ◯ | ◯ | ◯ |
| (11) P. Ex. 4/P. Ex. 6 | ◯ | ◯ | ◯ |
| (12) P. Ex. 4/P. Ex. 7 | X | ◯ | ◯ |

(◯: good, □: medium, X: poor)

Since the dicing film of Preparative Example 7 is a UV curable film, upon pick-up, a phenomenon occurs in which the cast polypropylene film as the core film was stripped from the dicing film and transferred to the die bonding adhesive film. This phenomenon is regarded as one type of poor pick-up.

In Summary Table 1 below, the numbers of the samples accord to those of the samples in Result Table 7.

SUMMARY TABLE 1
Properties of Shear Strength, Tensile Strength, Adhesion Force, Pick-up Performance, and Scattering of Chips

(adhesion unit: gf/25 mm)

| | | | | | | | | | | | |
|---|---|---|---|---|---|---|---|---|---|---|---|
| (1) | (2) | (3) | (4) | (5) | (6) | (7) | (8) | (9) | (10) | (11) | (12) |

| Shear Strength of Die Bonding Adhesive Film (N) | | 8.1 | 6.5 | 7.1 | 7.3 |
|---|---|---|---|---|---|
| Tensile Strength of Die Bonding Adhesive Film (Kgf/mm²) | | 1.55 | 0.50 | 1.35 | 1.41 |
| Adhesion Force between Die | UV | 2 | 54 | 81 | 77 |
| Bonding Adhesive Film and Wafer | No UV | 2 | 54 | 55 | 57 |
| Adhesion Force between Die Bonding | UV | 1 | 35 | 4 | 2 |
| Adhesive Film and Core Film | No UV | 1 | 36 | 35 | 35 |

| | | | | | | | | | | | | |
|---|---|---|---|---|---|---|---|---|---|---|---|---|
| Pick-up Performance | ◯ | ◯ | X | □ | □ | X | ◯ | ◯ | X | ◯ | ◯ | X |
| Die Breakage Upon Bonding | X | □ | □ | X | □ | □ | ◯ | ◯ | — | ◯ | ◯ | — |
| Die Scattering | X | X | X | ◯ | ◯ | ◯ | ◯ | ◯ | ◯ | ◯ | ◯ | ◯ |

The shear strength and tensile strength of the die bonding adhesive film, the adhesion force between the die bonding adhesive film and the wafer, and the adhesion force between the die bonding adhesive film and the core film, shown in Summary Table 1, are measured in a state in which the die bonding adhesive film is not laminated on the dicing film. As is apparent from Summary Table 1, in the case where the die bonding adhesive tape was prepared using the core film and by adding the UV curable low-molecular-weight compound to the adhesive film, the peel strength between the adhesive film and the adhesive layer of the base substrate when picking up a slim and large die was determined to be good. Further, when adding the butadiene copolymer, the degree of breakage of the slim and large die by compression upon die bonding was determined to be good.

Although the preferred embodiments of the die bonding adhesive tape of the present invention have been disclosed for illustrative purposes, those skilled in the art will appreciate that various modifications, additions and substitutions are possible, without departing from the scope and spirit of the invention.

As described above, the present invention provides a die bonding adhesive tape. According to the present invention, the die bonding adhesive tape uses a core film and comprises an adhesive film including an epoxy resin, an epoxy resin curing agent, a butadiene copolymer, and a UV curable low-molecular-weight compound. The core film is used, and the UV curable low-molecular-weight compound is cured by UV light, thereby improving pick-up performance when picking up slim and large dies. Further, the butadiene copolymer is used, thereby obtaining an excellent die bonding adhesive tape which does not cause breakage due to compression when bonding to slim and large dies.

What is claimed is:

1. A die bonding adhesive tape, comprising a base substrate and an adhesive layer formed on the base substrate, and having a structure in which a core film having a die bonding adhesive film attached thereto is bonded onto the adhesive layer.

2. The adhesive tape as set forth in claim 1, wherein the core film is a thermoplastic film having a thickness of 5˜100 μm, which is transparent to thus transmit UV light, and a difference in surface tension between both surfaces thereof is 70 dyne/cm or more.

3. The adhesive tape as set forth in claim 2, wherein the core film has a first surface having surface tension of 25˜40 dyne/cm and a second surface having surface tension of 45˜110 via corona surface treatment and a co-extrusion process.

4. The adhesive tape as set forth in claim 1, wherein the adhesive film has adhesion force of 30˜100 gf/25 mm to the core film before UV irradiation, and adhesion force of 30 gf/25 mm or less after UV irradiation.

5. The adhesive tape as set forth in claim 4, wherein a composition for the adhesive film comprises a UV curable low-molecular-weight compound in order to prepare the adhesive film having adhesion force of 30 gf/25 mm or less after UV irradiation.

6. The adhesive tape as set forth in claim 1, wherein a composition for the adhesive film comprises an acrylic copolymer having a molecular weight ranging from one million to three million, including a copolymer of acrylic acid ester or methacrylic acid ester or acrylonitrile.

7. The adhesive tape as set forth in claim 1, wherein a composition for the adhesive film comprises a butadiene copolymer having a molecular weight ranging from thirty thousand to four hundred thousand.

8. The adhesive tape as set forth in claim 1, wherein a composition for the adhesive film comprises a thermosetting resin composed mainly of an epoxy resin.

9. The adhesive tape as set forth in claim 8, wherein the composition for the adhesive film comprises a phenol resin for curing the epoxy resin.

10. The adhesive tape as set forth in claim 9, wherein the composition for the adhesive film comprises an imidazole-based curing accelerator for accelerating curing of the epoxy resin and the phenol resin.

11. The adhesive tape as set forth in claim 10, wherein the composition for the adhesive film comprises a phenone-based photoinitiator for accelerating curing of the UV curable low-molecular-weight compound.

12. The adhesive tape as set forth in claim 1, wherein the base substrate is a transparent film which transmits UV light, and is selected from among a polyethylene film, a polypropylene film, a polybutene film, a polybutadiene film, a polyvinyl chloride film, a polyethylene copolymer film, a polyurethane film, and combined films of one or more thereof.

13. The adhesive tape as set forth in claim 12, wherein the base substrate is imparted with surface tension of 75 dyne/cm or more through corona surface treatment.

14. The adhesive tape as set forth in claim 12, wherein the base substrate has a thickness of 70˜150 μm.

15. The adhesive tape as set forth in claim 13, wherein the base substrate has a thickness of 70˜150 μm.

16. The adhesive tape as set forth in claim 8, wherein a composition for the adhesive layer comprises an acrylic component, without a UV curable component, and is applied on the base substrate.

17. The adhesive tape as set forth in claim 15, wherein the composition for the adhesive layer is formed into a film through an application process using a knife coater or a gravure coater and then a drying process.

18. The adhesive tape as set forth in claim 15, wherein the adhesive layer has a thickness of 2˜30 μm.

19. The adhesive tape as set forth in claim 16, wherein the adhesive layer has a thickness of 2˜30 μm.
